(19) United States
(12) Patent Application Publication
(10) Pub. No.: US 2006/0087324 A1
(43) Pub. Date: Apr. 27, 2006

(54) E-field mapping

(75) Inventors: Magnus Berggren, Vreta Kioster (SE); Nathaniel D. Robinson, Linkoping (SE); Elias Said, Norrkoping (SE); David Nilsson, Mantorp (SE); Per-Olof Svensson, Norrkoping (SE); Jessica Hall, Norrkoping (SE)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: ACREO AB, Kista (SE)

(21) Appl. No.: 10/954,216

(22) Filed: Oct. 1, 2004

(51) Int. Cl. G01R 27/00

(52) U.S. Cl. 324/600

(57) ABSTRACT

The present invention provides a sensor device for measuring an electric field in a charge carrying medium. To this end, the sensor device defines a sensor space that is arranged to receive the charge carrying medium, and that comprises terminals for applying an electric field across the sensor space. Furthermore, sensor elements are arranged spatially separated in the sensor space. The sensor elements are operable to perform electrochemistry in response to the electric field and to change optical appearance upon said electrochemistry. Thereby electric field present in said sensor space is detectable from an optical appearance of said sensor elements.

### TECHNOLOGICAL FIELD OF THE INVENTION

The present invention relates to devices and methods for measuring electric fields in a charge carrying medium.

### TECHNOLOGICAL BACKGROUND

Measurement of local electric fields in a charge carrying medium is important in many applications. For example, the stability, selectivity, and efficiency of polymer electrolytes in fuel cells (PEFCs), polymer light emitting electrochemical cells (PLEC), batteries, and electrochemical sensors depend on the electric field distribution within the electrolyte. However, measurement of the electric field distribution within charge carrying media is typically performed in relatively cumbersome fashions.

Furthermore, the conductivity of electrolytes are conventionally evaluated as bulk properties using techniques such as Electronic Impedance Spectroscopy (EIS). EIS is a very powerful tool, but requires relatively complicated analysis and measurement equipments. Interpreting the results of solid and gel electrolytes can be especially difficult due to the flexing of the supporting structure. However, the conductivity of electrolytes can alternatively be determined from the electric field distribution therein, provided that it is known.

It is therefore an object of the present invention to provide a simple and low cost technique for performing electric field measurements in a charge carrying medium, such as an electrolyte or an electronic conductor.

### SUMMARY OF THE INVENTION

The above object is met by a sensor device as defined in claim 1, by the method as defined in claim 19, and by the system as defined in claim 21. The appended sub-claims define advantageous embodiments of the invention.

Hence, one aspect of the present invention provides a sensor device that defines a sensor space that is arranged to receive a charge carrying medium. The device comprises terminals for providing an electric field across said sensor space. The device furthermore comprises sensor elements that are spatially separated in the said sensor space and that are operative to perform electrochemistry in response to the electric field provided between the terminals. The sensor elements are constructed such that their optical appearance depends on the electrochemical state they are in. Hence, the optical appearances of the sensor elements change upon electrochemistry whereby an electric field present in said sensor space is detectable from an optical change in said sensor elements.

A sensor device as described above is highly advantageous in that it provides for indirect readings, provided by optical inspection of the device. In comparison, conventional devices typically require direct interaction using e.g. probes that measure the potential at different locations in the charge carrying medium. Additional advantages of the new system include low-complexity and ease of manufacturing.

The charge carrying medium can be selected from a wide variety of media, including gases, liquids, solids, and combinations thereof. For example, a solid material may be applied in the sensor space, the sensor may be dipped into a liquid, or exposed to a gas. For refined measurement of the field within the media, the sensor elements should preferably have a restricted spatial extension so that the measurement provided by each sensor element is comparable with a measurement taken at a singular point. This typically implies that each sensor element should occupy only a fraction of the space provided by the sensor space, for example one tenth, one hundredth, or one thousandth. However, if only course measurements are required, sensor size is not critical.

Hence, according to one embodiment, all the sensor elements together occupy less than half of said sensor space or even less than one fourth of said sensor space. The fraction of the sensor space occupied by the sensor elements is typically measured in terms of length in case of a one-dimensional sensor space, in terms of area in case of a two-dimensional sensor space, and in terms of volume in case a of three-dimensional sensor space.

According to one embodiment, the sensor device comprises a number of equal sensor elements having the same size, shape and constitution, such that every equal sensor element is operative to change optical appearance in the same fashion in response to an electrical field. Thereby the read-out provided by each equal sensor element is independent of the individual sensor element and can easily be compared with the read-out from another equal sensor element. Depending on the application at hand, it is possible to arrange a number of sets of equal sensor elements, such that element from the same set gives directly comparable read-outs whereas elements from different sets give potentially different read-outs. For example, sensor elements from different sets might react differently to different ions in the charge carrying medium.

According to one embodiment, the sensor elements each have a reduction side portion and a oxidation side portion, and the respective portions are operative to change optical appearance differently in response to said electric field. Basically, the respective portions are not defined per se in the sensor element. Rather, the portions are defined as a consequence of an applied electric field. In a sense, the respective portions are defined by the changes in optical appearance resulting from the electrochemistry. Thus, the position and size of the respective portions (visible by the change of optical appearance) can be used for determining the direction and magnitude of the electric field.

The optical appearance of many materials changes somehow upon electrochemical reaction. Hence, a large number of electrochemically active materials can be used in the sensor elements. According to one embodiment, the sensor elements are electrochromic whereby the optical appearance of the sensor elements changes in the visible domain. Thereby readings are available by ocular inspection or using for example conventional camera or scanner devices that operate in the visible domain.

According to an alternative embodiment, the sensor elements are operable to change optical absorption or emission in at least one of the infra-red domain and the ultra-violet domain. In such case, a ultra-violet or infra-red detector may be used for providing read-outs. Obviously, combinations of infra-red, visible, and ultra-violet detections can be used as well, depending on the particular material used in the sensor elements.

The invention described above thus provides a measure of the electric field present in the charge carrying medium. This is useful for many applications. For example, electrolytes can be analyzed for defects such as thickness variations, uniformity (of ion concentrations, mobility, etc.), existence of impurities etc. Alternatively, the sensor device can be used in connection with electrophoresis for observing electrophoretic motion of certain chemical species or particles.

Electrophoresis is basically the art of separating different components in a gel, liquid or gas, based on their mass, mobility, and charge. The particles are exposed to an electric field that induces electrostatic forces in the particles such that positive particles travel in one direction and negative particles travel in another direction. The speed of motion typically depends on the mass and mobility of the respective particle. The sensor device can be used to detect species after separation, directly in the separation medium (e.g. electrophoretic gel).

The sensor elements and the sensor space can have many different designs depending to the intended field of application. For example, according to one embodiment, the sensor space is a two-dimensional sensor surface, and the sensor elements are arranged in a two-dimensional pattern on that sensor surface. The two-dimensional pattern may, for example, include sensor elements arranged in a matrix along columns and rows. This arrangement provides for straightforward readings giving a measure of the electric field in two dimensions along the sensor surface. The pattern may include a limited number of sensor elements, reducing cost of manufacturing and simplifying the read-out but indeed also reducing the resolution of the read-out. Alternatively the pattern may comprise a large number of sensor elements (e.g. more than ten or even more than one hundred or one thousand sensor elements). Thereby a higher resolution is provided at the cost of increased complexity and cost.

Even though the two-dimensional pattern described above has advantages in terms of simplicity, some fields of application required three-dimensional measurements. Hence, according to one embodiment, the sensor space is a three-dimensional sensor volume, and the sensor elements are arranged in a three-dimensional pattern. A three-dimensional pattern obviously provides for a larger number of sensor elements, and for more detailed analyses of electric field distributions. Read-outs from three-dimensional sensor patterns may be provided using, for example, a confocal microscope or multiple cameras.

The sensor device described above is particularly advantageous since it can be manufactured using electrochemically active polymers. Such polymers have attracted considerable focus in recent years, partially due to their low cost and ease of production. Thus, according to one embodiment, the anode element, cathode element, and sensor elements comprise an electrochemically active polymer. The polymer can be selected from a large number of polymers, as exemplified further below. Depending on the application at hand, the same polymer may be used in all elements, or different polymers may be used in different elements. For example, according to one particular embodiment, the anode and cathode elements comprise a first polymer and the sensor elements comprise a second polymer.

According to one embodiment, the electrochemistry requires ions to be introduced into said sensor elements from said sensor space. In other words, the electrochemical activity in the sensor elements is conditioned by the addition of ions. Thereby, the electrochemical reaction and the resulting changes in optical appearance depend not only on the existence of an electric field, but also on the concentration and mobility of ions in the sensor space. Provided that the applied potential between the anode and cathode is known, the device can thereby be used for measuring the existence of ions in the sensor space. Furthermore, the mobility of the ions can be measured as well by taking consecutive measurements of the changes in optical appearance.

In other words, provided that the electric field is uniform across every sensor element, the rate of electrochemistry will be a direct indication of the respective ion conductivities at the respective sensor element.

In general, the conductivity for an ion conductive medium (i.e. an electrolyte) depends on the particular ionic species that are present in the medium. The conductivity is defined as

$$κ = {\sum }_{i} {z}_{i} {c}_{i} {μ}_{i}$$

where κ is the conductivity, z is the charge of ion specie i (2 for Ca²⁺, −1 for Cl⁻, etc.), c is the concentration of ion specie i, and μ is the mobility of ion specie i. Thereby, if for example concentrations are known it is possible get information about the mobilities, and vice versa, using standard analysis techniques e.g. involving salt with similar compounds.

Devices that respond to the existence of ions in the charge carrying medium can be used for many applications. For example, depending on the electrochemical material used in the sensor elements, different sensor elements might react differently to different type of ions. Some materials may provide for electrochemistry only in connection with a certain type of ion specie. Using such an electrochemically active material thus provides for selective measurements of the occurrence of certain ions. Alternatively, an ion selective material can be arranged on the sensor elements, operating as an ion filter giving the sensor element ion selective properties. Hence, according to one embodiment, the sensor elements are ion selective such that said electrochemistry requires ions belonging to a predefined set of ion species. Thereby, the electrochemistry is conditioned by the occurrence of ions belonging to the predefined set of ion species in the charge carrying medium. In effect, this provides a sensor device that is able to detect the presence of certain ions in the charge carrying medium.

In particular, polyaniline (PANI) has a unique characteristic of changing color with pH as well as with electrochemical reaction. Thus, PANI can be used both to detect electric fields and pH value at the same time.

According to one particular embodiment, the device is arranged with sensor elements of a first type having a first type of ion selective properties and sensor elements of a second type having a second type of ion selective properties. Thereby it is possible to perform simultaneous measurements of different ions.

The charge carrying medium can be many of many types. For example, the medium may be a prearranged electrolyte. In the context of the present invention, an electrolyte is a medium that carries ions with a sufficient mobility for performing electrochemistry. Hence, according to one embodiment, the device further comprises an electrolyte in the sensor space. The electrolyte may be arranged for measuring the electric field as such in a certain environment. Alternatively, the electrolyte may be applied on the device for testing or characterizing the electrolyte as such.

According to one particular embodiment, the electrolyte comprises an ion conducting polymer. Thereby it is possible to provide all-polymer devices, further reducing cost and complexity.

Alternatively, the sensor space is arranged to contact an arbitrary charge carrying medium. The latter is useful, for example, when measuring the characteristics of liquids or gases. According to one embodiment, the sensor surface comprises a charge carrying medium absorber. The absorber can be electrochemically inert, and will then act only to keep the medium in contact with the sensor surface.

The charge carrying medium may alternatively be an electronic charge carrier (i.e. an electronic conductor). Hence, according to one embodiment, the device comprises an electron conducting medium in the sensor space. In such a device, the sensor elements should be ion conducting and the electrochemistry involves ions from said sensor elements and electrons from said electron conducting medium. Consequently, the electrochemistry is primarily performed in the sensor elements at interfaces between said electrolyte and said sensor elements.

The electron charge carrier can, for example, be a layer of ITO deposited on a glass substrate (Indium Tin Oxide). In such case, the sensor element can be formed from an electrochemically active polymer such as PEDOT:PSS.

According to one embodiment, the sensor elements are ion and electron conducing making the sensor element self-sufficient in respect of electrochemistry, without electrochemical interaction with said charge carrying medium. Thereby the device only requires the charge carrying medium to distribute the electric field. The charge carrying medium may, for example, be platinum, which typically would not participate in electrochemistry.

According to one embodiment the sensor device is arranged with imaging means that is operative to create a digital image of said sensor elements, and analyzing means that is operative to receive and analyze said digital image and to detect changes in optical appearance of said sensor elements. Thereby the device is operative to provide quantified measurements of the electric field.

According to one particular embodiment, the analyzing means is operable to determine optical centroids of color density and to detect changes in optical appearance in terms of movements of said centroids. Analyzing movements of the centroids has proven to be a straightforward and effective way of quantifying the electric field. The centroids can be measured for a specific frequency of light, or for a set of frequencies. A particular advantage of using this approach is that conventional imaging and image analyzing equipment and methods can be employed, thereby reducing costs and complexity.

The sensor device is thus advantageous in that it provides a straightforward and low-cost device for measuring electric fields, and possibly also ion concentrations and mobilities, in a charge carrying medium. Depending on the number of sensor elements, the measurements can be restricted to a course, large-scale level, requiring only a few sensor elements, or it can be performed on a more detailed and refined level, requiring a larger number of sensor elements. In other words, aggregating a number of local, micro-level measurements provides for a macro-level measurement of the electric field in the ion conductive medium.

Another aspect of the invention provides a method for determining electric field in a charge carrying medium. The method includes the steps of

providing a sensor device as defined above,

introducing said charge carrying medium in said sensor space,

arranging an electrical voltage between said anode and cathode element,

analyzing the optical appearance of each sensor elements.

According to one embodiment, the step of analyzing the optical appearance involves establishing a digital image of the sensor elements and analyzing the digital image.

According to one embodiment, a number of consecutive images are taken separated in time. Since different ion species have different mobilities (both in the ion conductive medium and in the electrochemically active material of the sensor elements), the rate of change of the appearance of each sensor element gives information about the ion species in the ion conductive medium adjacent to that particular element. By taking multiple images while the sensors are switching after a change (increase, decrease or reversal) of the applied electric field and analyzing the images (either in real time or afterward), the individual concentrations (or mobilities) can be determined. For example, if testing an electrolyte that contains two species: Na that reacts quickly with the sensor material (such as PEDOT in PEDOT:PSS) and Ca that reacts slowly (either limited by chemical reaction mechanism or transport within the PEDOT:PSS or other sensor material), then the total ion conductivity in the ion conductive medium can be calculated from the final, steady-state measurement of the sensor coloration, while the relative concentrations of each of the two species can be determined from the speed at which the sensor elements switch.

Yet another aspect of the present invention provides a system for determining the electric field in a charge carrying medium. The system comprises a sensor device as defined above, an imaging device operative to create a (digital) image of said sensor elements, and analyzing means that is operative to receive and analyze said (digital) image and to detect changes in optical appearance of said sensor elements.

The sensor device thus measures an electric field induced in the ion conductive medium between the anode and cathode elements. However, straightforward optical inspection of the sensor elements only gives a relative measurement of the electric field, larger areas of reduction and oxidation indicate higher electric field but the absolute magnitude of the electric field may not be obvious per se. This can be handled in different ways. For example, knowing the total current flowing between the anode and the cathode and a few parameters regarding the ion conductive medium, (i.e. dimensions, uniformity etc.), it is possible to calculate the total current across any cross-section of the charge conductive medium. Knowing the total electric field across a certain cross-section, together with relative values at different positions along that cross-section provides for conversion of the relative values to absolute values since the sum of the current should equal the total current. The accuracy of such an estimate obviously depends to a large degree on the number of relative measurements that are taken along the cross-section.

Alternatively, absolute values can be provided using calibrated sensor elements. According to this approach, the sensor elements each have a well-defined shape and constitution, and respond in a pre-defined way to the application of an electric field. Thereby it is possible to use the amount of reduction/oxidation as a direct measure for the electric field.

Similarly, different materials (PANI, PEDOT:PSS, etc.) react at different rates with different materials. Hence, including two or more types of sensor elements (made of differing materials) or including two or more types of ion-selective membranes gives even more information about the occurrence of different ions in the ion conductive medium.

### BRIEF DESCRIPTION OF FIGURES

In the following, detailed descriptions of embodiments of the invention will be provided with reference to the non-limiting, exemplifying drawings on which:

FIG. 1 illustrates a sensor device having a two-dimensional array of polymer sensor elements.

FIG. 2 illustrates the pattern of the FIG. 1 device in more detail.

FIG. 3 illustrates the device of FIG. 1 when an electric field is distributed across the sensor elements, and also includes a close-up on one sensor element having a reduction side portion and an oxidation side portion.

FIG. 4 illustrates a set-up with a sensor device arranged in a flatbed scanner.

FIG. 5 illustrates a sensor device having the sensor elements arranged in a three-dimensional sensor space.

FIGS. 6(a) and (b) illustrate a calibration device, used for calibrating the response of a particular sensor element configuration.

FIGS. 7(a) and (b) illustrate a 9 columns by 11 rows sensor pattern in an non-switched state (FIG. 7(a)), and in a switched state (FIG. 7(b)) with an electric field acting on the sensor elements.

FIGS. 8(a) and (b) illustrate calculated electric field vectors for a device having a uniform electrolyte layer (FIG. 8(a)) as well as for a device having a non-uniform electrolyte layer (FIG. 8(b)).

FIG. 9 is a diagram showing the magnitude of centroid displacement versus applied electric field for the sensor element in the calibration device of FIGS. 6(a) and (b).

FIGS. 10(a) and (b) illustrate a cross-section of a sensor device, including charges flowing therein when an electric field is turned on.

FIG. 11 illustrates a comparison between experimentally measured field vectors (solid arrows) and isopotential and electric field lines and field vectors (dashed arrows displaced slightly to the right) calculated by solving Laplace's equation on device illustrated in FIGS. 7(a) and (b).

FIG. 12 illustrates an array of 35-micron electrochromic islands before (left) and after (right) 200 V was applied between the anode and cathode.

### DETAILED DESCRIPTION OF EMBODIMENTS

In preferred embodiments, the sensor element comprises, as electrochemically active material, an electrochromic polymer which is electrically conducting in at least one oxidation state, and optionally also comprises a polyanion compound such as poly(styrenesulfonate) (PSS). Electrochromic polymers for use in the sensor element are preferably selected from the group consisting of electrochromic polythiophenes, electrochromic polypyrroles, electrochromic polyanilines, electrochromic polyisothianaphthalenes, electrochromic polyphenylene vinylenes and copolymers thereof, such as described by J C Gustafsson et al in Solid State Ionics, 69, 145-152 (1994); Handbook of Oligo- and Polythiophenes, Ch 10.8, Ed D Fichou, Wiley-VCH, Weinhem (1999); by P Schottland et al in Macromolecules, 33, 7051-7061 (2000); Technology Map Conductive Polymers, SRI Consulting (1999); by M Onoda in Journal of the Electrochemical Society, 141, 338-341 (1994); by M Chandrasekar in Conducting Polymers, Fundamentals and Applications, a Practical Approach, Kluwer Academic Publishers, Boston (1999); and by A J Epstein et al in Macromol Chem, Macromol Symp, 51, 217-234 (1991). In a preferred embodiment, the electrochromic polymer is a polymer or copolymer of a 3,4-dialkoxythiophene, in which said two alkoxy groups may be the same or different or together represent an optionally substituted oxy-alkylene-oxy bridge. In the most preferred embodiment, the electrochromic polymer is a polymer or copolymer of a 3,4-dialkoxythiophene selected from the group consisting of poly(3,4-methylenedioxythiophene), poly(3,4-methylene-dioxythiophene) derivatives, poly(3,4-ethylenedioxythio-phene) (conventionally denoted PEDOT), poly(3,4-ethylene-dioxythiophene) derivatives, poly(3,4-propylenedioxythio-phene), poly(3,4-propylenedioxythiophene) derivatives, poly(3,4-butylenedioxythiophene), poly(3,4-butylenedioxy-thiophene) derivatives, and copolymers therewith. The polyanion compound is then preferably poly(styrene sulfonate) (conventionally denoted PSS). As is readily appreciated by the skilled man, in alternative embodiments of the invention, the electrochromic material comprises any non-polymer material, combination of different non-polymer materials, or combination of polymer materials with non-polymer materials, which exhibit conductivity in at least one oxidation state as well as electrochromic behaviour. Electrochromic elements comprising combinations of more than one polymer material, such as polymer blends, or several layers of electrochromic materials, wherein the different layers consist of the same material or different materials, e g one layer each of two different electrochromic polymers, are also contemplated.

For example, one could use a composite of an electrically conducting material and an electrochromic material, such as electrically conductive particles such as tin oxide, ITO or ATO particles with polymer or non-polymer electrochromic materials such as polyaniline, polypyrrole, polythiophene, nickel oxide, polyvinylferrocene, polyviologen, tungsten oxide, iridium oxide, molybdenum oxide and Prussian blue (ferric ferrocyanide).

Alternatively, a mixture of PEDOT and PSS (PEDOT:PSS) has proven to be particularly useful. This compound is commercially available as Orgacon® foil or aqueous dispersion from AGFA-Gaevert.

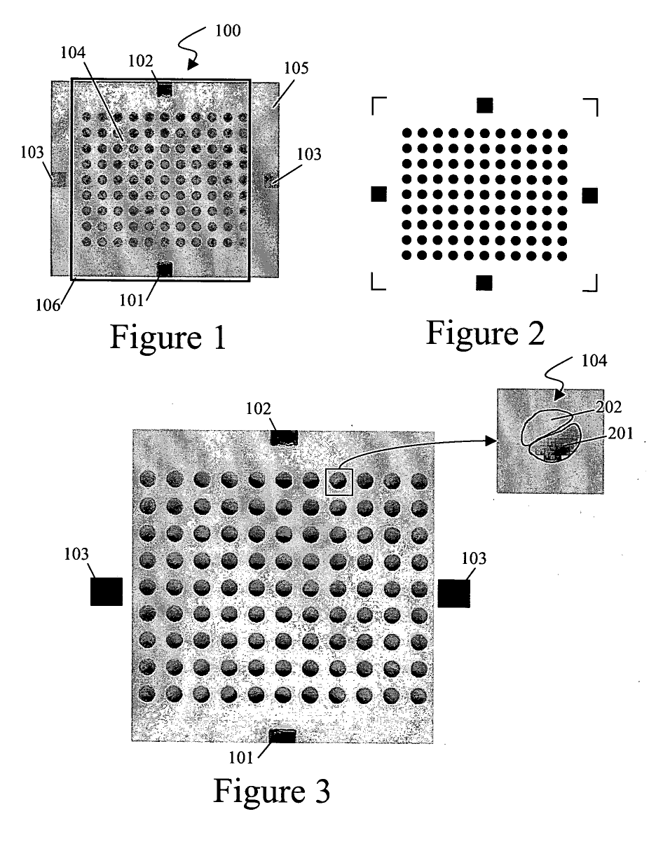

The sensor elements can be arranged in a two-dimensional pattern. Two-dimensional patterns are easily provided, for example by patterning an Orgacon® foil in a desired pattern. FIG. 1 illustrates a sensor device 100 having a two-dimensional pattern. The sensor device 100 comprises an anode 101, a cathode 102, two reference elements 103, and an array of sensor element 104 (11 columns by 9 rows). Each sensor element 104 is circular, and is formed of an electrochemically active polymer such as, for example, PEDOT. The elements are arranged on a carrier substrate 105. The carrier substrate can be rigid (e.g. glass) or flexible (e.g. paper or plastic foil). All elements except the reference elements 103 are subsequently covered by an electrolyte 106. The electrolyte might, for example, be a polymer electrolyte based on PSS. For clarity, FIG. 2 illustrates the pattern of electrochemically active material on the device illustrated in FIG. 1.

FIG. 3 illustrates the same device with an electric field applied between the anode 101 and cathode 102, such that an electric field is created in the electrolyte 106. The sensor elements can be interpreted as having a reduction side portion 201 and an oxidation side portion 202 in respect to the electric field in the electrolyte, as illustrated by the separately scaled-up sensor element 104 in FIG. 3. Using this interpretation, a potential difference is present between the oxidation and reduction side portions of each sensor element as a result of the electric field. The potential difference thereby induces a redox-reaction to occur in each sensor element 104, accompanied by an electronic current flowing within the sensor element between the oxidation and reduction side portions. The sensor elements consequently change optical appearance differently at the reduction side portion 201 and the oxidation side portion 202 in response to the electric field. Hence, the change of optical appearance is a result of each sensor element operating as a redox-system that is driven by the electric field, on a micro-level, in the charge carrying medium across the sensor element. This micro-level potential difference will thus induce oxidation at the oxidation side portion 202 of the element and reduction at the reduction side portion 201, and an electric current flowing within the sensor element 104 between the reduction side portion 201 and the oxidation side portion 202. The respective locations of the reduction and oxidation side portions depend on the actual direction of the micro-level electric field, and could very well differ from time to time. The only requirement on the sensor element is that the element must have a sufficient spatial extension along the direction of the potential difference so that the optical differences between the respective portions are detectable. In case of digital image analysis, elements as small as a couple of hundred nanometers in diameter are feasible (e.g. 500 nm). However, depending on the actual position of the oxidation 202 and reduction 201 side portions, indicated by changes in optical appearance, the direction of the electric field in the charge carrying medium is readily observable. Furthermore, the sizes and degree of color change of the respective side portions 201, 202 give measurement of the magnitude of the electric field.

A sensor device 100 as illustrated in FIGS. 1-3 can be analyzed in different ways. For example, ocular inspection of the colors of the sensor elements gives a straightforward indication of the electric field distribution in the electrolyte.

However, the sensor device can alternatively be analyzed using an imaging device. For example, as illustrated in FIG. 4, a sensor device 402 can be placed in a conventional flatbed scanner 401, and the digitizer 410 in the scanner can register the optical appearance of the sensor elements 403. This method has obvious advantages in that conventional, low-cost table-top equipment can be used. Furthermore, the resulting image provided by the scanner can be analyzed using ordinary image analyzing software (e.g. a simple algorithm in Matlab®). Thereby it is possible to derive a vector for each sensor element indicating the direction and magnitude of the electric field, simply by analyzing the movement of a color density centriod for each sensor element. The color density centroid is basically center of mass for one or more color frequencies.

When analyzing the sensor elements, the reference elements 103 mentioned above can be used as reference for the optical appearance. The reference elements are typically not exposed for the electric field, and consequently maintain their original, pristine optical appearance.

Hence, the present invention provides a measurement of both the magnitude and direction of the electric field in the charge carrying medium on a micro-level (adjacent to each sensor element). Taking a number of micro-level measurements enable aggregation of the micro-level measurements to a macro-level measurement that provides an estimate of the electric field distribution within the entire charge carrying medium (e.g. electrolyte).

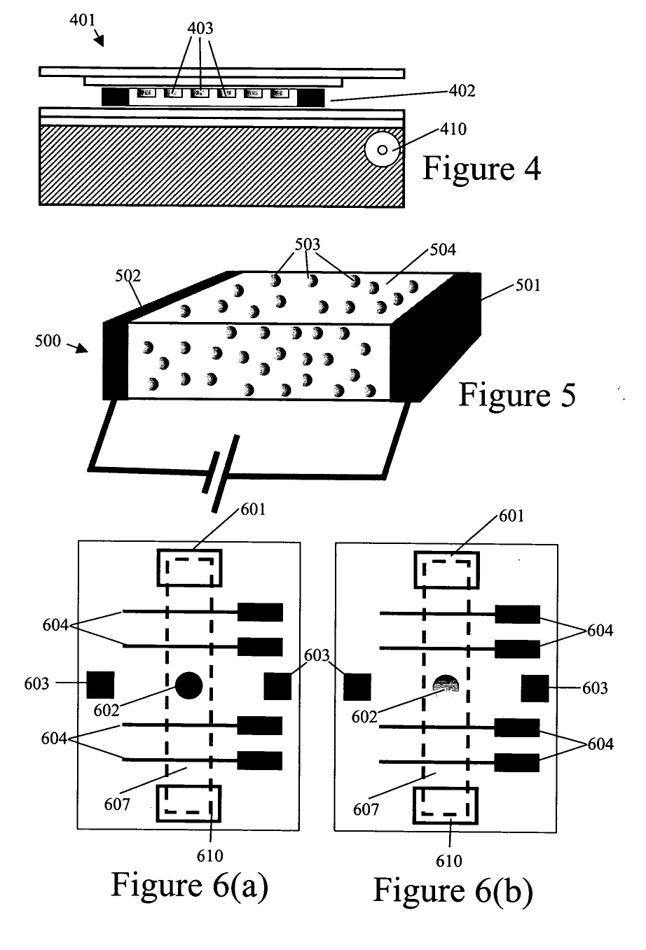

Alternatively, as illustrated in FIG. 5, the sensor elements can be arranged in a three-dimensional pattern, enabling three-dimensional measurement. The three-dimensional sensor device 500 illustrated in FIG. 5 comprises an anode 501, a cathode 502, sensor elements 503, and a charge carrying medium 404. Thereby it is possible to measure the electric field distribution in three-dimensional space.

Three-dimensional systems can be made in many fashions. A straight-forward approach from a manufacturing perspective is to stir aqueous, electrochemically active polymer (e.g. PEDOT:PSS) into an electrolyte in which the electrochemically active polymer is insoluble. Thereby a three-dimensional pattern of islands (i.e. sensor elements) will be formed by the polymer in the electrolyte. The islands do not need to be regularly spaced, although regularity typically makes calculations easier. Observing the spatial configuration and the optical appearance of the sensor element is possible using, for example, a confocal microscope or an imaging device that can focus on different distances (over the thickness of the charge carrying medium).

One way of providing regularly spaced three-dimensional sensor element patterns is to arrange the elements in different layers. For example, a carrier material such as paper can be used for printing sensor elements on, and a number of such sheets can be stacked on top of each other to form a three-dimensional pattern. The paper can then act as absorber for a subsequently applied charge carrying medium such as a liquid electrolyte. In alternative designs, the paper can be exchanged for layers of electrolyte or some other carrier material that keeps the sensor element in a predefined three-dimensional pattern. Depending on how the optical appearances of the sensor elements are to be registered, the carrier material should provide for sufficient optical transparency. It might, for example, be sufficient for the carrier material to be transparent for ultra-violet light only (or infra-red), provided that ultra-violet (infra-red) detection of the electrochemistry in the sensor elements is employed.

As stated above, a structure as described above can be analyzed using, for example, an ordinary flatbed scanner that is attached to a personal computer. The image thereby obtained can be analyzed with standard image processing techniques. In case the image is a RBG (Red Green Blue) image and a polymer of a single color is used (like PEDOT:PSS) it is typically sufficient to analyze only one color channel, e.g. the red channel. In such case the red channel is analyzed on a sensor element basis, in order to determine the coordinates of the center of color density. Subtracting the coordinates of the actual mid-point of the corresponding element from the color density information will result in a non-zero vector for each element provided that the element has experienced an electric field. Moreover, the resulting vector will be directed in parallel with that electric field and will have an absolute magnitude that is a function of the magnitude of the electric field.

In order to provide sensor elements having well-defined characteristics, a calibration device can be formed that provides for exact measurement of the behavior of a certain sensor element design. An example of such a calibration device will be given below.

The electrochemical devices according to the present invention can be exploited in a wide range of applications, including electrolyte testing, particularly for finding variations in mobility or ion concentration, or for testing anisotropic electrolytes.

In addition, a vast number of medical applications are envisaged. For example, the sensor device can be used for replacing fluorescent die when determining the location of proteins, DNA fragments, or other molecules during or after electrophoretic separation. Based on the same principle, it is also possible to track cations, anions, and larger molecules during electrophoresis. This is possible since the ion concentration in the electrolyte influences the speed at which each sensor element switches. Such measurements can be performed during (rather than after) electrophoresis.

In case the sensor elements are formed out of an ion-sensitive electrochromic polymer or are coated with ion-selective membranes, the device according to the present invention can be used for determining the local concentration of different species. Actually, ion selectivity can be introduced in several ways. For example, an ion-selective membrane between the sensor elements and the electrolyte causes the color change to occur at a rate depending on the concentration of the permitted ions. Adjacent sensor elements having different membranes can be used to determine relative concentrations. An array of such elements can be used to map the concentrations of several different kinds of ions over a large area. Furthermore, more complex electrochromic polymers like polyaniline (PANI) have different color states depending on their redox states and ion concentrations (pH). Therefore, field and ion concentrations can be determined locally throughout the medium adjacent to the sensor device. In addition, multi-color materials such as PANI enable more complex analysis, since multiple parameters can be derived measuring multiple color frequencies.

Some polymers are themselves selective to different ions, either through their chemical kinetics or though ion transport. Obviously, no additional membrane is required using such polymers.

When the rate of color change is measured, it is possible to measure interactions at the interface between the ion conductive medium and the sensor elements. Any change in the interface that affects the rate at which ions are transported across the interface will change the speed of each pixel. Such measurements could include detection of the presence of specific macromolecules provided that an appropriate receptor molecule has been attached to the sensor element. This can be done by considering the effect the detected molecules have on the rate of transfer of ions from the bulk electrolyte into the polymer layer (the molecules thus act like a membrane with variable ion permeability). Alternatively, a receptor molecule can be used that releases or consumes an ion when it connects with the molecule to be detected.

It is also possible to detect the presence of any ion inhibitor at the sensor surface. The extra substance could be transferred before the electrolyte is applied. The resulting device would then measure changes in the inhibiting medium (caused by, for example, reaction with bioactive material).

The senor device for measuring electric field is useful for optimization of materials in, and mechanical design of, batteries and fuel cells. Furthermore, the sensor can be used as an ion detector in or after electrophoretic separations. For example, as a simple ion transport measurement device, the uniformity in ionic conductivity and thickness of an electrolyte applied during a manufacturing process can be measured for quality improvement and control.

Experiment

In the following, experiments will be described with reference to FIGS. 6-12.

Calibration devices were manufactured by removing all but the PEDOT:PSS shown in black FIGS. 6(a) and (b) from an Orgacon® foil (PEDOT:PSS thickness of 200 nm) obtained from AGFA-Gaevert using photolithography and a reactive ion etch. The same structures can also be produced using simpler methods like screen printing. The PEDOT:PSS pattern comprises electrode fingers 604, reference elements 603 and a sensor element 602. After removal of the photoresist, an anode 601 and cathode 610 were constructed from Ag paste (DuPont 5000 polymer Silver Conductor) without further chemical modification. Cu has also been demonstrated as a suitable electrode material. A 100-micron thick plastic foil mask was temporarily adhered to the substrate outside the electrolyte area 607. Electrolyte (40 wt % PSS, 10 wt % D-Sorbitol, 10 wt % glycerol, 40 wt % deinoized water) was spin-coated over the entire device to a thickness of roughly 80 μm. The plastic foil mask was then removed, patterning the electrolyte in a lift-off fashion. The electrolyte conductivity is sensitive to the humidity of the surroundings. All measurements were made in a laboratory environment with a relative humidity of 40%.

An electric field was established in the devices by applying a potential between the anode 601 and cathode 610 using a Keithley 2400 source meter. The current driven through the device was measured simultaneously by the same instrument. The electric field within the electrolyte on the calibration structure was measured via the potential difference between the thin PEDOT:PSS electrodes 604 that extend under the electrolyte using a high-impedance (100 GΩ) data acquisition card (National Instruments PCI-MIO-16E-4). Images of the entire device were acquired using a Canon CanoScan 9900f flatbed scanner at 400 DPI resolution. Since both the current through the device and the optical adsorption in the sensor element 602) change dramatically over the course of several seconds, the images were captured and current recorded 150 seconds after each change in applied potential.

Upon application of a potential between the Ag electrodes, electrochemistry changes the absorption in the sensor element 602 of the devices as shown in FIG. 6(b). To quantify the change, and relate it to the applied field, the calibration device was used to simultaneously measure the current and the potential at four locations in the electrolyte and to record the image of the round polymer island. The final result is a calibration between electric field and the degree of electrochemical rearrangement in the sensor element 602.

The calibration measurement yields two results. The first result is the conductivity of the electrolyte, which comes directly from:
κ=jL/ΔV
where j is the current density (current divided by the thickness t and width w of the electrolyte), ΔV is the potential measured between two of the four fingers shown, and L is the distance between the measured fingers. The use of four fingers in the calibration device allows for thee independent measurements of the field to be obtained for statistical purposes.

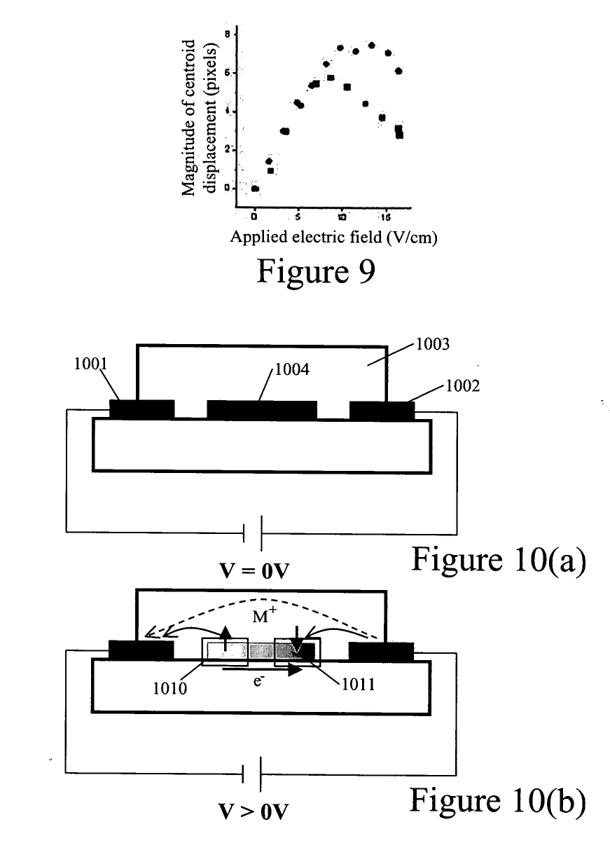

The second result of the calibration is the degree of switching in the sensor element 602 as a function of the applied electric field (approximately ΔV/L as measured above). This was quantified by calculating the displacement of the centroid of the pixel intensity of the red channel of the image of the polymer island obtained with the scanner. The pixel intensity of the red channel was linearly scaled such that the clear plastic foil gave a value of zero and pristine (unswitched) PEDOT resulted in a value of 100. The latter reference was based on the average intensity from two squares of PEDOT covered with isolated electrolyte placed on the left and right edges of the device, as visible in FIGS. 1 and 2. A square area including and surrounding each polymer island was then used to calculate a corresponding centroid location via:

$$\overline{x} = \frac{{\sum }_{j = 1}^{n} {x}_{j} {m}_{j}}{{\sum }_{j = 1}^{n} {m}_{j}} ; \overline{y} = \frac{{\sum }_{j = 1}^{n} {y}_{j} {m}_{j}}{{\sum }_{j = 1}^{n} {m}_{j}}$$

where mⱼ is the color density at pixel (xⱼ, yⱼ). The vector resulting from subtracting the coordinates of the centroid of the island after a field was applied (between the anode and cathode of the device) from the coordinates observed before any potential was applied indicates the magnitude and direction of the applied field. The relationship between the vector magnitude and the applied electric field measured using the calibration device shown in FIGS. 6(a) and (b) is shown in FIG. 9. FIG. 9 is a diagram showing the magnitude of centroid displacement (pixels) versus applied electric field (V(cm). Notice that at fields above 8 V/cm (2 V/sensor element) the centroid displacement decreases again. This is caused by the irreversible over-oxaidation of the polymer which destroys the material and hence the device. This places an effective limit on the maximum field measurable with a device based on 3 mm islands. This maximum scales approximately as the inverse of the diameter of the island.

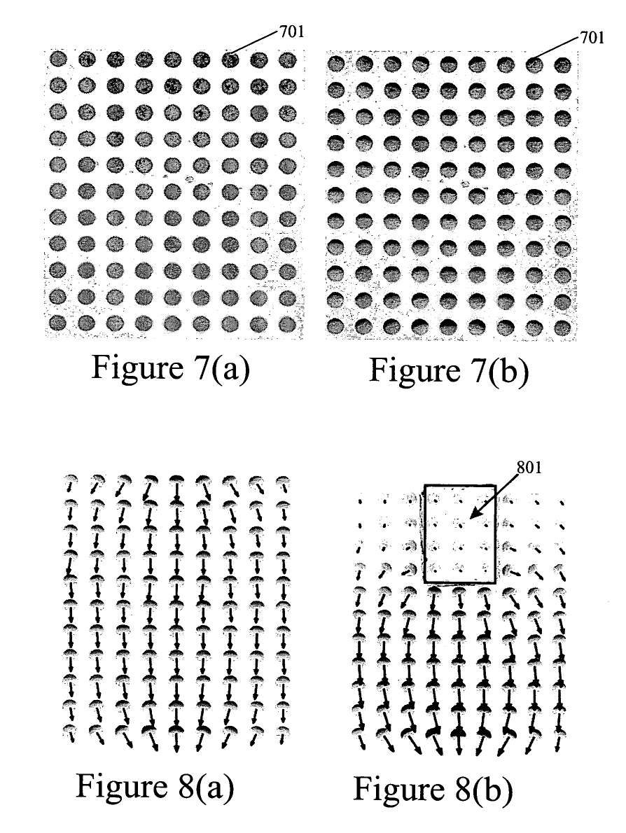

To demonstrate the power of electrochromism as an indicator of electric field, a demonstrator consisting of 9 columns by 11 rows of sensor elements 701 was manufactured using the same technique described for the calibration device above, as illustrated in FIGS. 7(a) and (b). The observed change in the absorption within the islands can be seen by comparing FIGS. 7(a) and 7(b). The electric field, calculated at each island as described above, is shown as white arrows in FIG. 8(a) on top of a false color image of the red channel intensity (scaled as described above). The result of a more complex experiment is shown in FIG. 8(b), where a region 801 of the uniform electrolyte was replaced with the same electrolyte at eleven times the thickness.

In the traditional sense, electrochromism is driven by applying a potential directly to an electrochemically active material (PEDOT:PSS, for example) relative to the potential of an adjacent electrolyte through the use of a counter electrode. Assuming sufficient electronic conduction in the electrochromic material and sufficient ion conduction in the electrolyte, the electronic potential (and therefore the electrochemical potential) variation within each material domain is relatively small, and the polymer electrode is uniformly converted from one doping level to another. Electrochromism can, however, be induced within a single electrode if the potential variation along the electrode, either in the electrode itself or in the adjacent electrolyte, is sufficient. The difference in applied potential within the electrode causes electrochemistry to occur, reducing the material (in this case, PEDOT:PSS) at the end with lower potential while oxidizing the end at the higher potential. The concentration of doped versus undoped PEDOT adjusts until the electrochemical potential reaches a uniform state (equilibrium). The electrochromic effect can be seen as the result of local difference in electrochemical potential between the polymer and adjacent electrolyte.

Electrochromism can likewise be induced by a gradient in electrostatic potential within the electrolyte, as shown in FIGS. 6(b) and 7(b). The ionic current driven between an anode and cathode (completely separate from the polymer film being observed) causes an electrostatic field in the electrolyte, and consequently a gradient in electrochemical potential. The initially uniform doped polymer in an insulated island of PEDOT, however, has an (approximately) uniform electrostatic potential, since electronic charge transport within the material quenches potential gradients in conducting materials. The result is a difference in electrochemical potential between the electrolyte and polymer that drives oxidation in the island at points where the electrochemical potential of the conducting polymer is higher than that of the electrolyte and reduction where the electrochemical potential pf the electrolyte is higher than that of the polymer. This continues until a steady-state is achieved, where the electrochemical potential within the polymer is in equilibrium with the adjacent electrolyte. The result is a gradient in the absorption of visible light within the electrochromic polymer island that is related to the direction and magnitude of the electric field in the electrolyte.

The principles of induced electrochromism in an isolated film of PEDOT:PSS are illustrated in FIGS. 10(a) and (b). FIGS. 10(a) and (b) illustrate a cross-section of a sensor device, comprising a cathode 1001, an anode 1002, a sensor element 1004, and a charge carrier 1003 (electrolyte). Once equilibrium is achieved, current no longer passes through the sensor element 1004 via the electronic mechanism and the ionic conduction through the 200 nm thick film will be insignificant (compared to the thickness of the 80 μm thick electrolyte 1003, the figure is not true to scale). Thus, the electric field in the electrolyte 1003 will be undisturbed, meaning that it will be identical to the field that would occur if the sensor element 1004 were not present (except within the Debye screening length of the sensor element). When the electric field is removed, the reversible doping and dedoping mechanism returns the sensor element to its original uniform state.

The reason for the electrochromism induced in the polymer island in the technique presented here can alternatively be described via an analogy with parallel conduction paths. Charges (cations, M³⁰ in FIG. 10(b)) to be transported from the anode 1002 to the cathode 1001 can take one of two paths, as illustrated in FIG. 10(b). The first involves the electrolyte 1003 exclusively, as with a normal electrochemical cell. The second takes advantage of the electronic conductivity of the sensor element 1004. First, the ionic current is transduced to an electronic current at the near edge of the sensor element. The current is then carried as electrons e⁻ (or rather polarons/bipolarons) to the far edge of the island, where the electronic current is again transduced to an ionic current in the electrolyte again in order to reach the cathode. Each unit of charge that is transported through the polymer island “consumes” oxidation sites 1011 (reduction sites 1010) at the side nearest to (farthest from) the anode as shown in FIG. 10(b). Thus, once the previously described equilibrium is obtained, the second conduction path is no longer available for charge transport and further mass transport for electrochemistry between the anode and cathode must be supported entirely by the electrolyte. This can also be observed by comparing the current in a device with a sensor element to that in the same device minus the sensor element. Initially the current will be higher in the device with the second conduction path. After the polymer is consumed, only the electrolyte is available for conduction and the two devices show the same current density. From this description, it becomes clear that the relative resistance to conduction between the two paths determines the extent of reaction in the sensor element.

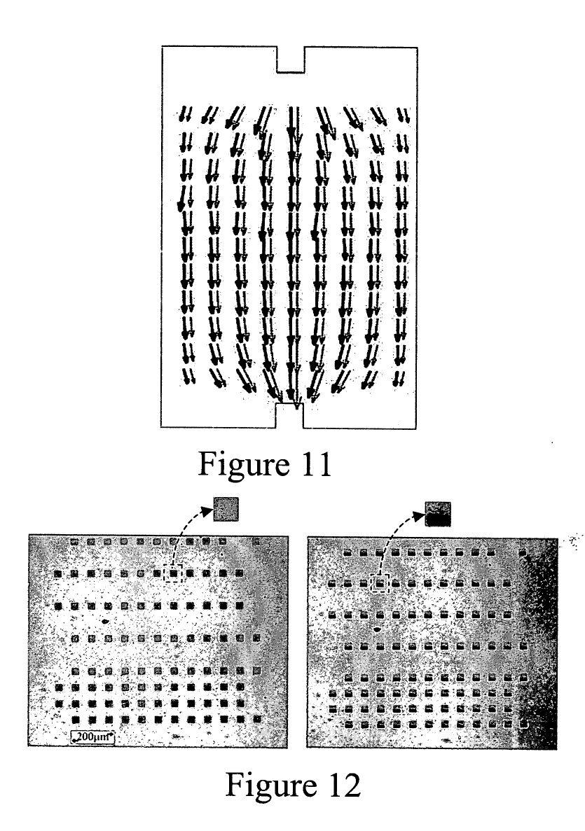

The result shown in FIG. 7(a) demonstrates a simple application of visualizing electric fields in an electrolyte. As expected for a simple geometry with uniform electrolyte conductivity and thickness, the field lines diverge from the anode and converge at the cathode, employing the whole width of the electrolyte in the center region (far from both the anode and cathode), as can be seen from the arrows indication the field magnitude and direction calculated from each polymer island in the matrix. In order to verify these values, they were compared with a numerical solution to Laplace's equation on the same geometry, as shown in FIG. 11. In the theoretical calculation, the conductivity of the electrolyte was assumed constant and uniform and the boundaries were insulating except for the anode and cathode which were given a constant potential (1 and 0 respectively). The field lines, connecting the small square anode (top) and cathode (bottom), and isopotential contours (perpendicular to the field lines) are the result of this calculation and are shaded with the local potential. The field vectors (solid arrows) calculated from the experiment agree well with the numerical solution of Laplace's equation, also shown as dashed arrows displaced slightly to the right of the measured vectors (but calculated from the same locations). The larger errors in the field vectors were caused by small bubbles in the electrolyte, visible upon close inspection of FIG. 7(a), that interfere with the centroid calculation (and possibly the field on the electrolyte). Hence, this set-up clearly demonstrates the ability of the present invention to detect defects in an electrolyte.

The experiment shown in FIG. 8(b) was used as a demonstration of the device for measuring local electrolyte characteristics. Given the geometry of the altered region and the assumption that the electrolyte within that region was uniform, a least-square fit of a finite difference approximation of Laplace's equation yields a thickness ratio of 14.6 which should be compared with the value 11 targeted during patterning. The exact thickness and the uniformity of the electrolyte in both regions are unknown, but an error of 30% is not unexpected due to the challenge of patterning a small area of thicker electrolyte.

Although originally demonstrated at a relatively large length scale (islands in the previously described devices were 3 mm in diameter, separation was 2 mm), the induced electrochromism used in this technique is visible at much smaller dimensions. FIGS. 12(a) and 12(b) show an irregular array of square islands (35 μm on each side) of PEDOT:PSS under an electrolyte both before and after a potential was applied to an anode and cathode (not shown). The electrodes were much wider that the array of square islands. The switch is clearly visible in the microscope image and the same technique described for the larger devices could be used to determine the electric field in the electrolyte at this length scale. Theoretically, the dimensions can be reduced to the limit that the optical absorption within each polymer island can be observed and quantified.

1. A sensor device defining a sensor space that is arranged to receive a charge carrying medium, said sensor space comprising terminals for applying an electric field across said sensor space and sensor elements arranged spatially separated in said sensor space, said sensor elements being operable to perform electrochemistry in response to said electric field and to change optical appearance upon said electrochemistry such that electric field present in said sensor space is detectable from an optical appearance of said sensor elements.

2. A sensor according to claim 1, wherein in said sensor elements are electrochromic and said optical appearance of said sensor elements are operable to change in the visible domain.

3. A sensor according to claim 1, wherein said optical appearance of the sensor elements are operable to change in at least one of the infra-red domain and the ultra-violet domain.

4. A sensor device according to claim 1, said sensor device comprising a number of equal sensor elements having the same size, shape and constitution, such that every equal sensor element is operative to change optical appearance in the same fashion in response to an electrical field.

5. A sensor device according to claim 1, wherein said sensor elements occupies less than half of said sensor space.

6. A sensor device according to claim 1, wherein said sensor space is a two-dimensional sensor surface on which said sensor elements are arranged in a two-dimensional pattern.

7. A sensor device according to claim 1, wherein said sensor space is a three-dimensional sensor volume in which said sensor elements are arranged in a three-dimensional pattern.

8. A sensor device according to claim 1, wherein said anode element, cathode element, and sensor elements comprise an electrochemically active polymer.

9. A sensor device according to claim 1, wherein said sensor elements are electron conducting and said electrochemistry requires ions from said charge carrying medium and is performed at interfaces between said charge carrying medium and said sensor elements, whereby said electrochemistry is conditioned by the occurrence of ions in said sensor space.

10. A sensor device according to claim 9, wherein said sensor elements are ion selective such that said electrochemistry requires ions belonging to a predefined set of ion species, whereby said electrochemistry is conditioned by the occurrence of ions belonging to said predefined set of ion species in said charge carrying medium.

11. A sensor device according to claim 10, arranged with sensor elements of a first type having a first type of ion selective properties and sensor elements of a second type having a second type of ion selective properties.

12. A sensor device according to claim 1, further comprising an electrolyte forming a charge carrying medium in said sensor space.

13. A sensor device according to claim 12, wherein said electrolyte comprises ion conducting polymer.

14. A sensor device according to claim 1, further comprising an electron conducting medium in said sensor space, wherein said sensor elements are ion conducting and said electrochemistry involves ions from said sensor elements and electrons from said electron conducting medium and is performed at interfaces between said electrolyte and said sensor elements.

15. A sensor device according to claim 1, wherein the sensor elements are ion and electron conducing such that said electrochemistry in each sensor element is self-sufficient without electrochemical interaction with said charge carrying medium.

16. A sensor device according to claim 1, said sensor elements having a reduction side portion and a oxidation side portion, whereby said sensor elements are operative to change optical appearance differently at said reduction side portion and said oxidation side portion in response to said electric field.

17. A sensor device according to claim 1, further arranged with imaging means that is operative to create a digital image of said sensor elements, and analyzing means that is operative to receive and analyze said digital image and to detect changes in optical appearance of said sensor elements.

18. A sensor element according to claim 17, wherein said analyzing means is operable to determine optical centroids and to detect changes in optical appearance in terms of movements of said centroids.

19. A method for determining electric field in a charge carrying medium, including the steps of
providing a sensor device as defined in claim 1,
introducing said charge carrying medium in said sensor space,
establishing an optical appearance of each sensor element,
arranging an electrical voltage between said anode element and said cathode element,
analyzing changes in the optical appearance of each sensor elements.

20. A method according to claim 19, wherein the step of analyzing involves determining movements of a color density centroid of each sensor element.

21. A system for determining the electric field in a charge carrying medium, comprising a sensor device as defined in claim 1, an imaging device operative to create an image of said sensor elements, and analyzing means that is operative to receive and analyze said image and to detect changes in optical appearance of said sensor elements.

22. A system as according to claim 21, wherein said image is a digital image.
